(19) United States
(12) Patent Application Publication
(10) Pub. No.: US 2010/0171092 A1
(43) Pub. Date: Jul. 8, 2010

(54) METHOD FOR CONTROLLING OPTIC INTERBAND TRANSITION OF CARBON NANOTUBES, THE CARBON NANOTUBES RESULTING THEREFROM AND DEVICES THAT COMPRISE THE CARBON NANOTUBES

(75) Inventors: Seonmi YOON, Yongin-si (KR); Jaeyoung CHOI, Suwon-si (KR); Hyeon Jin SHIN, Suwon-si (KR); Young Hee LEE, Suwon-si (KR); Ki Kang KIM, Suwon-si (KR)

Correspondence Address: CANTOR COLBURN, LLP, 20 Church Street, 22nd Floor, Hartford, CT, 06103, US

(73) Assignee: Samsung Electronics Co., Ltd., Suwon-si (KR)

(21) Appl. No.: 12/370,202

(22) Filed: Feb. 12, 2009

(30) Foreign Application Priority Data
Jun. 11, 2008 (KR) 10-2008-0054588

(51) Int. Cl. H01L 29/66; H01L 21/04; H01L 31/0352

(52) U.S. Cl. 257/9; 438/542; 257/E29.168; 257/E31.033; 257/E21.042; 977/742; 977/954

(57) ABSTRACT

A new single optical interband transition occurs at the corresponding p-doping state of the carbon nanotubes in the VIS-NIR region when the degree of p-doping of carbon nanotubes is increased beyond a certain degree. P-doped carbon nanotubes to exhibit the new single optical interband transition in the VIS-NIR region may be used for devices so as to improve sensitivity and selectivity of the devices.

### CROSS REFERENCE TO RELATED APPLICATION

This application claims priority to Korean Patent Application No. 2008-0054588, filed on Jun. 11, 2008, and all the benefits accruing therefrom under U.S.C. §119, the contents of which in its entirety are herein incorporated by reference.

### BACKGROUND

1. Field

This disclosure relates to a method for controlling optic interband transition of carbon nanotubes (“CNTs”), CNTs resulting therefrom and devices using the CNTs.

2. Description of the Related Art

Electrical properties of carbon nanotubes (“CNTs”) may depend on their diameter and/or chirality. In general, CNTs may exhibit a conductivity similar to that of metals (such CNTs being referred to metallic CNTs) when the chirality indices (n, m) meet the relationship |n−m|=3q (where q is an integer). Further, CNTs may exhibit semiconducting characteristics (such CNTs being referred to as semiconducting CNTs) when ·n—m|≠3q.

One-dimensional CNTs may have characteristic electron density of states such as a step-like electron density of states in the valence band and the conduction band. The step-like electron density of states may be referred to as Van Hove singularities. The optical spectra of CNTs occurring in the VIS-NIR region may be due to the various optical transitions between Van Hove singularities. Semiconducting CNTs may exhibit E₁₁^{S} and E₂₂^{S} absorbance peaks in the VIS-NIR region, which may correspond to the first and second transitions. In contrast, metallic CNTs may exhibit E₁₁^{M} absorbance peaks, which may correspond to the first transition. The position of the optic transition peaks may be dependent on diameter and chirality of the CNTs. For example, CNTs with a diameter of about 1 nm may exhibit three distinct optic absorbance bands near about 0.7 eV (E₁₁^{S}), about 1.2 eV (E₂₂^{S}) and about 1.8 eV (E₁₁^{M}).

### SUMMARY

A new single optic interband transition may occur at the corresponding p-doping state of the carbon nanotubes (“CNTs”) in the VIS-NIR region. P-doped CNTs exhibit a new optic interband transition in the VIS-NIR region. These P-doped CNTs may be used for devices so as to improve sensitivity and selectivity (purity) of the devices.

Disclosed herein are p-doped CNTs exhibiting a single optic interband transition at the corresponding p-doping state of the carbon nanotubes in the VIS-NIR region.

Disclosed herein too is a device, which includes the p-doped CNTs.

Disclosed herein too is a method for controlling optic interband transition of CNTs including controlling the p-doping of CNTs so that a single optic interband transition occurs at the corresponding p-doping state of the CNTs in the VIS-NIR region.

Disclosed herein too is a method of p-doping CNTs including controlling p-doping of CNTs so that a single optic interband transition occurs at the corresponding p-doping state of the CNTs in the VIS-NIR region.

### BRIEF DESCRIPTION OF THE DRAWINGS

The above and other aspects, features and advantages of the invention will be more apparent by describing in further detail exemplary embodiments thereof with reference to the attached drawings, in which:

FIGS. 1(a), 1(b) and 1(c) are graphs showing the change of density of states of semiconducting carbon nanotubes (“CNTs”) depending on the progress of p-doping. In the FIGS. 1(a), 1(b) and 1(c), the X axis represents energy (eV) and the Y axis represents density of states (arbitrary units);

FIG. 2 is a graph showing reduction potential depending on diameter and chirality of CNTs, where the X axis represents 1/diameter (in nanometers (“nm”)) and the Y axis represents reduction potential (eV) [reduction potential (“V”) versus Normal Hydrogen Electrode (“NHE”)];

FIG. 3 is an UV-VIS-NIR absorbance spectrum of CNTs depending on the concentration of oxidizing agent in Example 1, where the X axis represents energy (eV) and the Y axis represents absorbance (arbitrary units);

FIGS. 4(a) and 4(b) are Raman spectra of CNTs depending on the concentration of oxidizing agent in Example 1, where the X axis represents Raman shift (cm⁻¹) and the Y axis represents intensity (arbitrary units) respectively;

FIG. 5 is an UV-VIS-NIR absorbance spectrum of CNTs depending on the concentration of oxidizing agent in Example 2, where the X axis represents wavelength (nm) and the Y axis represents absorbance (arbitrary units);

FIG. 6 is an UV-VIS-NIR absorption spectrum according to FIG. 5 with the X-axis changed into energy (eV), where the Y axis still represents absorbance (arbitrary units).

### DETAILED DESCRIPTION

Exemplary embodiments now will be described more fully hereinafter with reference to the accompanying drawings, in which exemplary embodiments are shown. The invention may, however, be embodied in many different forms and should not be construed as limited to the exemplary embodiments set forth herein. Rather, these exemplary embodiments are provided so that this disclosure will be thorough and complete, and will fully convey the scope of the invention to those skilled in the art. In the description, details of well-known features and techniques may be omitted to avoid unnecessarily obscuring the presented embodiments.

The terminology used herein is for the purpose of describing particular embodiments only and is not intended to be limiting of the invention. As used herein, the singular forms “a”, “an” and “the” are intended to include the plural forms as well, unless the context clearly indicates otherwise. Furthermore, the use of the terms a, an, etc. do not denote a limitation of quantity, but rather denote the presence of at least one of the referenced item. The use of the terms “first”, “second”, and the like do not imply any particular order, but are included to identify individual elements. Moreover, the use of the terms first, second, etc. do not denote any order or importance, but rather the terms first, second, etc. are used to distinguished one element from another. It will be further understood that the terms “comprises” and/or “comprising”, or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the drawings, like reference numerals in the drawings denote like elements. The shape, size and regions, and the like, of the drawing may be exaggerated for clarity.

Right after preparation, carbon nanotubes (“CNTs”) may exhibit a slight p-doping state. The degree of p-doping may be increased by oxidizing the CNTs using an oxidizing agent. Examples of suitable oxidizing agents used for p-doping of the CNTs may include acids such as hydrochloric acid, sulfuric acid, nitric acid, and the like, metal salts such as gold chloride, silver nitride, and the like, nitronium compounds such as nitronium hexafluoroantimonate (NHFA), and the like, or a combination comprising at least one of the foregoing oxidizing agents.

If the degree of p-doping of CNTs is gradually increased, the original optical transition characteristics may disappear. Further, if the degree of p-doping of CNTs goes beyond a certain degree, new optical transition characteristics may occur. The term “new optical transition” is used since it is a newly occurred optical transition and different from the original optical transitions. Examples of ways for increasing the degree of p-doping of CNTs may include increasing the concentration of oxidizing agent used for p-doping of the CNTs, increasing the treatment time using the oxidizing agent or using a stronger oxidizing agent, and the like.

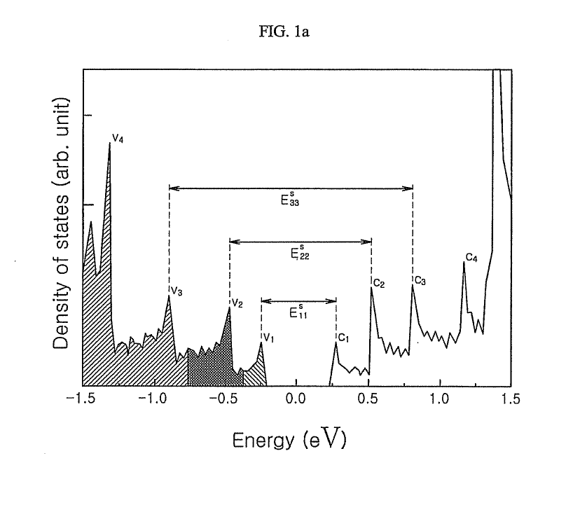

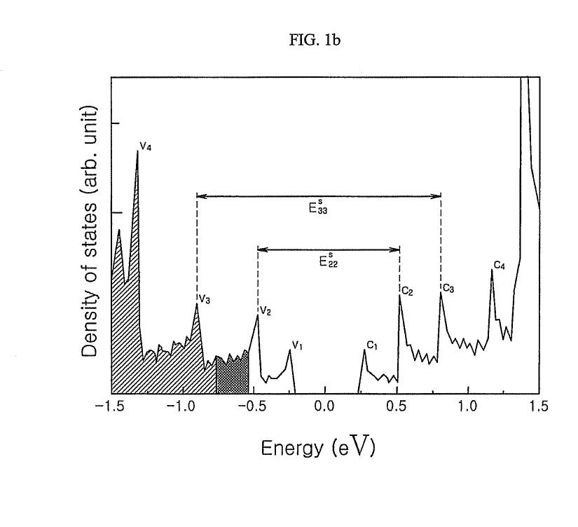

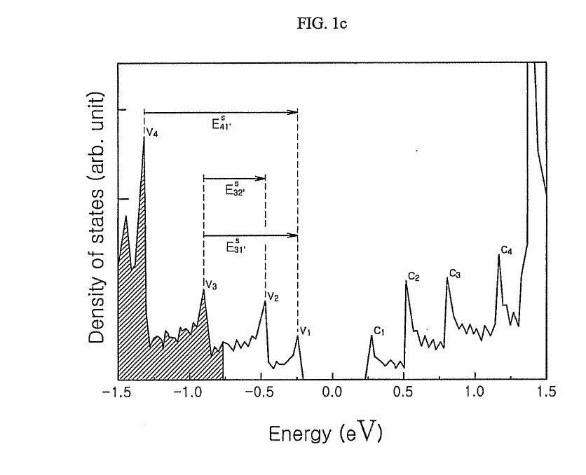

FIG. 1 is a graph showing the change of density of states (“DOS”) of semiconducting carbon nanotubes (“CNTs”) depending on the progress of p-doping according to an exemplary embodiment (see Example 1), where the X axis represents energy (eV) and the Y axis represents density of states (arbitrary units) respectively in FIGS. 1(a), 1(b) and 1(c). FIG. 1(a) shows the DOS before p-doping of the CNTs, FIG. 1(b) shows the DOS after weakly p-doping the CNTs and FIG. 1(c) shows the DOS after strongly p-doping the CNTs.

Sharp peaks (Van Hove singularities) may be seen in FIG. 1(a). It may be also seen that several optical interband transitions may occur between the in valence band and the conduction band at the corresponding doping state. For reference, n in Eₙₙ is an index representing each band. Before p-doping CNTs, in the UV-VIS-NIR region, E₂₂^{S} and Eₙ^{S} transitions may occur in semiconducting CNTs, and E₁₁^{M} transition may occur in metallic CNTs.

Referring to FIG. 1(b), it may be seen that, after weak p-doping, optic interband transitions may be reduced as holes may be produced in the valence band and the electron density may decrease.

Referring to FIG. 1(c), it may be seen that, as the degree of p-doping is increased so as to dope the second valence band, a new optical interband transition may occur in the valence band.

That is, CNTs having a new optical interband transition may be obtained by increasing the degree of p-doping of CNTs. The newly occurring optical interband transition may be a single optical interband transition at the corresponding p-doping state. The single optical interband transition may be contrasted with the multiple optical interband transitions between the valence band and the conduction band before p-doping of the CNTs (FIG. 1(a)) or after weak p-doping of the CNTs (FIG. 1(b)). Multiple optical interband transitions in CNTs may decrease sensitivity and selectivity (purity) of devices utilizing the CNTs. In contrast, a device utilizing CNTs having a single optical interband transition may have improved sensitivity and selectivity (purity).

In an exemplary embodiment, doping may be carried out to induce the change of electron density at the second or upper valence bands in order to produce a new optical interband transition. This may be further reviewed with regard to the reduction potential of oxidizing agent.

Reduction potential of CNTs may vary depending on their diameter and/or chirality.

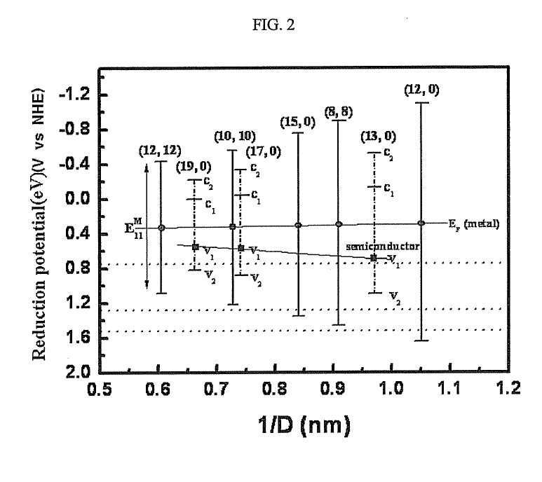

FIG. 2 is a graph showing reduction potential depending on diameter and chirality of CNTs, where the X axis represents 1/diameter (the diameter being measured in nanometers (“nm”)) and the Y axis represents reduction potential (measured in electron volts (“eV”))[reduction potential (“V”) versus Normal Hydrogen Electrode (“NHE”)].

Referring to FIG. 2, it may be seen that the reduction potential of the oxidizing agent may be at least 0.8 eV (V vs NHE) in order for the doping to occur at the second or upper valence band. An oxidizing agent having a higher reduction potential may be used in light of the ability of higher reduction potentials to produce new optical interband transition. Further, increasing the treatment time with the oxidizing agent or increasing the amount of the oxidizing agent relative to that of the CNTs (in a given mixture comprising the oxidizing agent, a solvent and the CNTs) may be available in light of the production of the new optical interband transition.

The amount of the oxidizing agent based on the CNTs may be expressed as moles of the oxidizing agent dissolved in 1 liter (“L”) of a solvent per 1 gram (“g”) of the CNTs (i.e., molar concentration of the oxidizing agent per 1 g of the CNTs). In terms of producing a single optical absorption interband transition, avoiding unnecessary waste of oxidizing agent and preventing possible damages or dissolution of the CNTs caused by excessive use of the oxidizing agent (oxidizing agent other than metal salt, as described below), the molar concentration of the oxidizing agent per 1 g of the CNT may be controlled to be about 0.5 M to about 1000 M. The molar concentration of the oxidizing agent may be determined with respect to the oxidizing agent treatment time, the reduction potential of the oxidizing agent, and other parameters.

For the same reason, the oxidizing agent treatment time at the oxidizing agent concentration may be controlled to be about 1 second to about 10 hours. A shorter treatment time may be used although the concentration of the oxidizing agent may have to be increased in order to produce the desired effect. Conversely, a longer treatment time may be used if the concentration of the oxidizing agent is reduced. Therefore, it may be said that the concentration of the oxidizing agent and the treatment time are inversely related to each other.

When an oxidizing agent other than metal salt is used, it may be possible that damage or dissolution of the CNTs may occur if the degree of p-doping of CNTs is increased beyond a level where the new single optical interband transition has been produced. Accordingly, the degree of p-doping of CNTs may be controlled to as the point where the single optical interband transition is first observed in the VIS-NIR region.

The CNTs that are treated to exhibit the single optical interband transition in the VIS-NIR region may be used in a variety of devices. Non-limiting examples of the devices may include optical sensors such as NIR sensors.

By controlling the new optical interband transitions in the VIS-NIR region, it may be possible to control the work function of the CNTs. The controlling of the work function may be used for various applications. Examples of such applications include band gap control in a PN junction device. Examples of PN junction devices may include solar cell, PN junction diode, complimentary metal-oxide-semiconductor (CMOS), thermoelectric devices, and the like.

The examples and experiments will now be described. The following examples and experiments are for illustrative purposes only and not intended to limit the scope of the present invention.

### EXAMPLES

### Example 1

A single-walled carbon nanotubes (“SWCNTs”) powder (available from Iljin Nanotech) is used. A SWCNT film (about 41 millimeters (“mm”)×about 41 mm) is prepared on quartz by dispersing the SWCNTs powder in dichloroethane (DCE). The SWCNTs have a transmittance of about 88% at the wavelength of about 550 nanometers (“nm”). 0.1 milligrams (“mg”) of the SWCNTs are used to form the 41 mm×about 41 mm film that displays a transmittance of about 88%.

After heat-treatment and completely removing the solvent adsorbed on the surface, a pristine SWCNT film is prepared.

Gold chloride (AuCl₃) is used as oxidizing agent. Gold chloride is dissolved in nitromethane to prepare solutions respectively having concentrations about 0.5 millimolar (“mM”), about 1 mM, about 10 mM, about 20 mM, about 30 mM, about 50 mM, about 60 mM and about 80 mM.

Doping is carried out by dip-coating or spin-coating each of the solutions on the prepared SWCNT film. The oxidizing agent treatment time is about 30 seconds. For reference, doping the 41 mm×about 41 mm film (to produce the new optical interband transition) by dipping may require at least about 3 mL of solution.

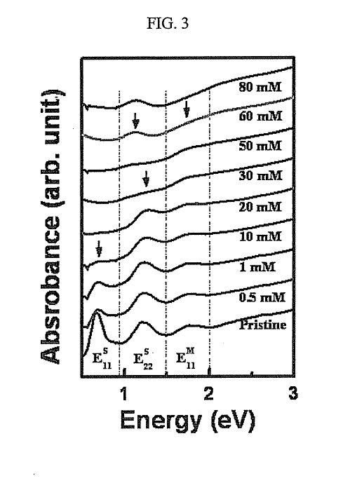

FIG. 3 is an UV-VIS-NIR absorbance spectrum for CNTs that were doped in solutions having different concentrations of gold chloride. From the FIG. 3, it can be seen that the spectra vary depending on the concentration of gold chloride (i.e., the concentration of the oxidizing agent Au³⁺ in Example 1, where the X axis represents energy (eV) and the Y axis represents absorbance (arbitrary units). For reference, the UV-VIS-NIR spectra was obtained by measuring absorbance at about 200 to about 2400 nm using a UV-VIS-NIR spectrometer (Cary 5000).

Referring to FIG. 3, it may be seen that the original optical interband transitions may disappear gradually when the degree of p-doping is increased by increasing the concentration of gold chloride. For example, the E₁₁^{S} peak may disappear when the concentration of gold chloride is about 10 mM. When the concentration of gold chloride reaches about 20 mM, all the E₁₁^{S}, E₂₂^{S} and E₁₁^{M} peaks disappear. A new optic interband transition appears as the concentration of gold chloride increases further. For example, a new peak appears when the concentration of gold chloride reaches about 60 mM. The reaction time may be short when doping the film as is demonstrated by this Example. Accordingly, a large amount of oxidizing agent may be used (i.e., the concentration of the oxidizing agent may be increased) to attain a new peak. In the case of doping by adsorption, the oxidizing agent not adsorbed on the film may be removed during the processing. In the case, the amount of the oxidizing agent remaining on the film may be reduced.

Work function value (eV) is measured for the p-doped CNTs in this example. Photoelectron spectrometer (surface analyzer, AC-2, Riken Keiki CO., LTD.) is used for measuring the work function. Measured work function values are shown in the Table 1 below with the concentrations of the gold chloride. For reference, work function may vary according to the optical interband transition. Therefore, even in cases where other dopants such as nitronium hexafluoroantimonate (NHFA) are used as in Example 2, the same work function value may be obtained at the same optical interband transition state.

TABLE 1

| Concentration of | |
|---|---|
| gold chloride (mM) | Work function (eV) |
| 0 | 4.8 |
| 0.5 | 4.93 |
| 10 | 4.99 |
| 20 | 5.53 |
| 50 | 5.7 |
| 60 | 5.81 |
| 80 | 5.9 |

As seen in Table 1, work function values may be controlled variously when the optical interband transition is controlled. In other words, when the degree of p-doping is increased, work function may be increased. The new single optical interband transition may be shown after work function is about 5.7 eV or more.

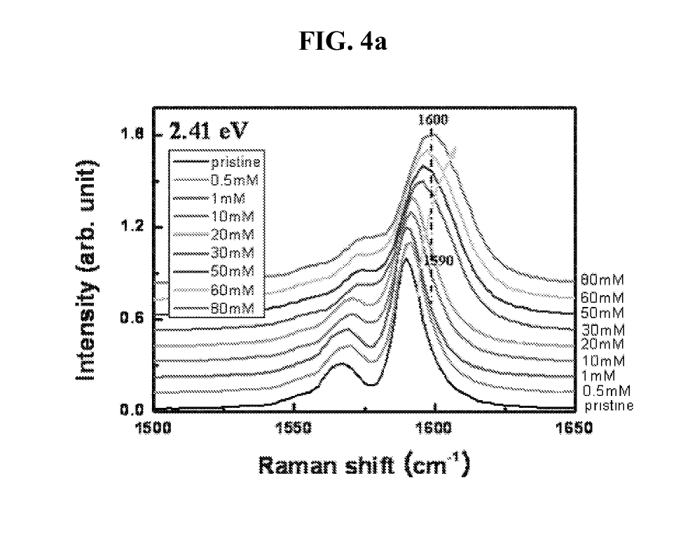

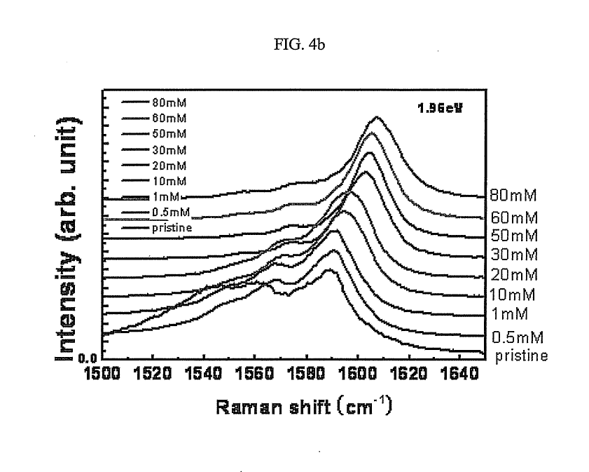

FIG. 4 is a Raman spectra (Renishaw, RM1000-Invia) of CNTs depending on the concentration of gold chloride in Example 1, where the X axis represents Raman shift (cm⁻¹) and the Y axis represents intensity (arbitrary unit) respectively in FIGS. 4(a) and 4(b). FIGS. 4(a) and 4(b) show the Raman spectra at 2.41 eV and 1.96 eV, respectively.

Referring to FIGS. 4(a) and 4(b), the upshift of the G band may show that the degree of p-doping may be increased as the concentration of gold chloride is increased.

### Example 2

A solvent mixture of dichloroethane (DCE) and tetramethylene sulfone (TMS) is used. The weight ratio of the solvents is 1:1. Nitronium hexafluoroantimonate (NHFA) is added to the mixture to prepare 30 mL of solutions respectively having concentrations of 0.05 mM, 0.1 mM, 0.5 mM, 1 mM, 2 mM, 3 mM, 4 mM, 5 mM, 10 mM, 20 mM, 50 mM, 100 mM and 800 mM. 3 mg of CNTs are mixed with 30 mL of the solution and dispersed using a sonicator for 10 hours. Then, p-doped CNTs are obtained by centrifuging the CNTs.

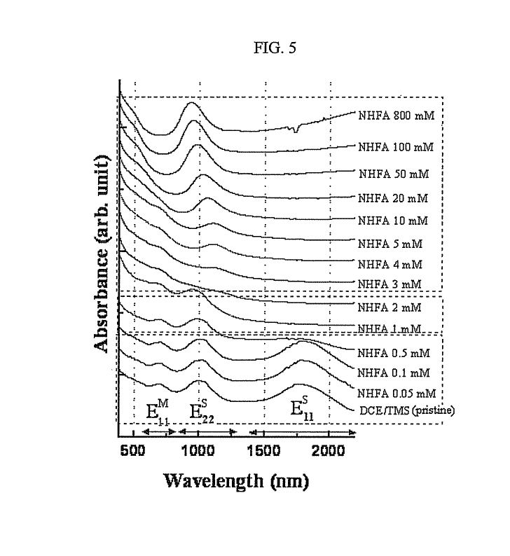

FIG. 5 is an UV-VIS-NIR absorbance spectrum of CNTs depending on the concentration of NHFA (i.e., the concentration of the nitronium ion oxidizing agent) in Example 2, where the X axis represents wavelength (nm) and the Y axis represents absorbance (arbitrary units). As in Example 1, UV-VIS-NIR absorbance is measured from 200 to 2400 nm using a UV-VIS-NIR spectrometer (Cary 5000).

Referring to FIG. 5, it may be seen that a similar absorbance pattern can be seen when p-doping is carried out weakly at a low concentration of the oxidizing agent (i.e., when NHFA concentration is 0.05 mM to 0.1 mM). That is, when p-doping is carried out weakly, E₁₁^{M}, E₂₂^{S} and E₁₁^{S} peaks may appear.

When the degree of p-doping is increased, the E₁₁^{S} peak disappears (when NHFA concentration is 0.5 mM). When the degree of p-doping is increased to an intermediate level, the E₂₂^{S} peak disappears (when NHFA concentration is 2 mM).

When p-doping is carried out strongly by further increasing the degree of p-doping, a new peak may appear in the VIS-NIR region (when NHFA concentration is about 3 to about 800 mM).

Such a change in the peaks of the absorption spectra may be caused by a change in the valence band as electrons are removed, which leads to the occurrence of the new optical interband transition in the valence band.

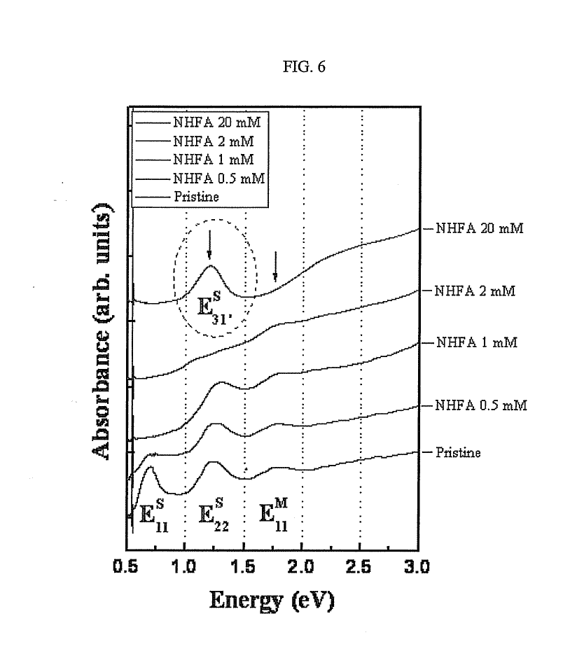

FIG. 6 is an UV-VIS-NIR absorption spectrum with the X-axis changed into energy (eV), where the Y axis still represents absorbance (arbitrary units). FIG. 6 shows graphs of the case where p-doping is not carried out (DCE/TMS; i.e., pristine), weak p-doping is carried out (NHFA concentration of about 0.5 mM), intermediate p-doping is carried out (NHFA concentration of about 1 to about 2 mM), and strong p-doping is carried out (NHFA concentration of about 20 mM).

Referring to FIG. 6, it may be seen that an optical absorption transition (E_{31′}^{S}) may appear at about 1.2 eV (corresponds to a wavelength of about 900 to about 1000 nm) as the degree of p-doping is increased.

As described above, optical interband transition may be controlled in the VIS-NIR region by controlling the degree of p-doping of CNTs. As a result, p-doped CNTs with a single optical interband transition may be attained at the corresponding doping state.

While the exemplary embodiments have been shown and described, it will be understood by those skilled in the art that various changes in form and details may be made thereto without departing from the spirit and scope of the present invention as defined by the appended claims.

In addition, many modifications can be made to adapt a particular situation or material to the teachings of the invention without departing from the essential scope thereof. Therefore, it is intended that the present invention not be limited to the particular exemplary embodiments disclosed as the best mode contemplated for carrying out this invention, but that the present invention will include all embodiments falling within the scope of the appended claims.

What is claimed is:

1. P-doped carbon nanotubes exhibiting a single optical interband transition at the corresponding p-doping state of the carbon nanotubes in the VIS-NIR region.

2. The p-doped carbon nanotubes according to claim 1, wherein the carbon nanotubes are p-doped using an oxidizing agent having a reduction potential of 0.8 eV or more, when the voltage is measured versus a normal hydrogen electrode.

3. The p-doped carbon nanotubes according to claim 2, wherein the carbon nanotubes are p-doped using a metal salt or a nitronium compound as the oxidizing agent.

4. The p-doped carbon nanotubes according to claim 2, wherein a concentration of the oxidizing agent is about 0.5 molar to about 1000 molar based on 1 gram of the carbon nanotubes.

5. The p-doped carbon nanotubes according to claim 1, wherein a work function of the carbon nanotubes is 5.7 eV or more.

6. A device comprising p-doped carbon nanotubes, wherein the carbon nanotubes exhibit a single optical interband transition at the corresponding p-doping state of the carbon nanotubes in the VIS-NIR region.

7. The device according to claim 6, wherein the device is an optical sensor.

8. A method for controlling optical interband transition of carbon nanotubes comprising:
immersing carbon nanotubes in an oxidizing solution; the immersion being continued for a period effective to produce a single optical interband transition at a corresponding p-doping state of the carbon nanotubes in the VIS-NIR region.

9. The method for controlling optical interband transition of carbon nanotubes according to claim 8, wherein the degree of p-doping of the carbon nanotubes is increased till the single optical interband transition is detected.

10. The method for controlling optical interband transition of carbon nanotubes according to claim 9, wherein the degree of p-doping is increased by increasing a strength of an oxidizing agent in which the carbon nanotubes are immersed, increasing a concentration of the oxidizing agent in which the carbon nanotubes are immersed, or increasing a treatment time for which that carbon nanotubes are immersed in the oxidizing agent.

11. The method for controlling optical interband transition of carbon nanotubes according to claim 8, wherein the p-doping is controlled in order for a work function of the carbon nanotubes to be 5.7 eV or more.

12. A method for p-doping carbon nanotubes comprising:
immersing carbon nanotubes in an oxidizing solution to produce a single optical interband transition at a corresponding p-doping state of the carbon nanotubes in the VIS-NIR region; the oxidizing solution comprising oxidizing agents selected from the group consisting of acids, metal salts, nitronium compounds or a combination comprising at least one of the foregoing oxidizing agents.

13. The method for p-doping carbon nanotubes according to claim 12, wherein the p-doping is carried out until electron density of the second or upper valence band of the carbon nanotubes is changed.

14. The method for p-doping carbon nanotubes according to claim 12, wherein the p-doping is controlled in order for a work function of the carbon nanotubes to be 5.7 eV or more.
